(19) United States
(12) Patent Application Publication
(10) Pub. No.: US 2004/0165632 A1
(43) Pub. Date: Aug. 26, 2004

(54) Semiconductor laser device and manufacturing method thereof

(75) Inventors: Nobuhiro Ohkubo, Ikoma-shi (JP); Fumie Kunimasa, Tenri-shi (JP)

Correspondence Address: Barry E. Bretschneider, Morrison & Foerster LLP, Suite 300, 1650 Tysons Boulevard, McLean, VA, 22102, US

(73) Assignee: SHARP KABUSHIKI KAISHA, Osaka (JP)

(21) Appl. No.: 10/786,479

(22) Filed: Feb. 26, 2004

(30) Foreign Application Priority Data
Feb. 26, 2003 (JP) 2003-049117

(51) Int. Cl. H01S 5/00

(52) U.S. Cl. 372/45

(57) ABSTRACT

A semiconductor laser device, which is made from an AlGaInP-based material, comprising:

a first clad layer of a first conductivity type, an active layer and a second clad layer of a second conductivity type that are formed over a semiconductor substrate,

wherein a portion of said active layer in an area near a laser resonator end face has a peak wavelength in photoluminescence that is smaller than a peak wavelength in photoluminescence in a portion of said active layer in a laser resonator inner area, and the second clad layer of the second conductivity type located in the area near a laser resonator end face contains As atoms, and a manufacturing method thereof.

### BACKGROUND OF THE INVENTION

1. Field of the Invention

The present invention relates to a semiconductor laser device that is used for an optical disc and a manufacturing method thereof, and more specifically concerns a window-structure semiconductor laser device that has superior characteristics in its high-output operation and a manufacturing method thereof.

2. Description of the Related Art

In recent years, various kinds of semiconductor lasers have been widely used as light sources for optical disc devices. In particular, high-output semiconductor lasers have been used as writing light sources for discs in DVD players, DVD-RAM drives and the like, and there have been strong demands for higher output semiconductor lasers.

One of the factors that limit the developments of higher output semiconductor layers is catastrophic optical damage (COD) that occurs in an active layer area near a laser resonator end face in response to an increase in the light output density.

The reason for the occurrence of the COD is that the active layer area near a laser resonator end face serves as an absorbing area for laser light. On the laser resonator end face, many non-radiation recombination centers, which are referred to as surface states or interface states, exist. Since carriers, which are injected into the active layer near the laser resonator end face, are lost by the non-radiation recombination, the injection carrier density in the active layer near the laser resonator end face is smaller in comparison with that in the center portion. As a result, with respect to the wavelength of the laser light formed by a higher injection carrier density in the center portion, the active layer area near a laser resonator end face forms an absorbing area.

When the light-output density becomes higher, local heat generation becomes greater in the absorbing area, causing a temperature rise and the subsequent reduction in band-gap energy. This results in a positive feedback in which the absorbing coefficient becomes further greater to cause a temperature rise; thus, the temperature of the absorbing area near a laser resonator end face finally reaches the melting point, causing COD.

One of the methods for providing higher outputs of a semiconductor laser while improving the COD level has been proposed by Japanese Patent Application Laid-Open No. Hei 3-208388, and in this method, a window structure, formed by disorganizing the active layer, is utilized.

With respect to the conventional technique of a semiconductor laser having this window structure, FIG. 8 shows a structural drawing of a semiconductor laser device disclosed in Japanese Patent Application Laid-Open No. Hei 3-208388.

In FIG. 8, FIG. 8(a) is a cross-sectional view showing a semiconductor laser in an exciting area (active area), and FIG. 8(b) is a cross-sectional view showing a semiconductor laser in an impurity diffusion area (window area).

Reference numeral 1001 is an n-type GaAs substrate, 1002 is an n-type GaAs buffer layer, 1003 is an n-type AlGaInP clad layer, 1004 is an undope GaInP active layer, 1005 is a p-type AlGaInP inner clad layer, 1006 is a p-type AlGaInP outer clad layer, 1007 is a p-type GaAs cap layer, 1008 is an n-type GaAs block layer, 1009 is a p-type GaAs contact layer, 1011 is a p-side electrode, and 1012 is an n-side electrode.

Referring to a process drawing in FIG. 9, the following description will discuss a manufacturing method of the above-mentioned conventional semiconductor laser device.

By using a MOVPE method, the following layers are successively formed on an n-type GaAs substrate 1001 at a growth temperature of 660° C.: an n-type GaAs buffer layer 1002, an n-type AlGaInP clad layer 1003, an undope GaInP active layer 1004, a p-type AlGaInP inner clad layer 1005, a p-type GaInP etching stop layer, a p-type AlGaInP outer clad layer 1006, a p-type GaInP hetero barrier layer and a p-type GaAs cap layer 1007. The respective layers 1005 to 1007 having the p-type conductivity are doped with Zn atoms as p-type impurities.

As shown in FIG. 9(a), a dielectric film 1013 is vapor-deposited on the p-type GaAs cap layer 1007, and after forming this layer into a striped pattern by using a photolithography method, Zn impurities are diffused therein by using a sealed-tube diffusion method in which ZnAs2 is applied as an impurity diffusion source. Thus, high density Zn atoms are diffused into the undope GaInP active layer 1004 within an impurity diffusion area so that band-gap energy increases in the active layer.

After a resist stripe mask 1014 has been again formed on the dielectric film 1013 and the p-type GaAs cap layer 1007 by using a photolithography method as shown in FIG. 9(b), the dielectric film 1013, the p-type GaAs cap layer 1007, the p-type GaInP hetero barrier layer and the p-type AlGaInP outer clad layer 1006 are successively removed by using chemical etching processes so that a ridge is formed, as shown in FIG. 9(c).

After the resist stripe mask 1014 has been removed as shown in FIG. 9(d), the n-type GaAs block layer 1008 is allowed to selectively grow by using the dielectric film 1013 as a mask through an MOVPE method at a growth temperature of 660° C. Thus, an n-type GaAs block layer is formed on areas on the outside of the ridge as well as on the impurity diffusion area so that a current injection is inhibited in these areas.

The dielectric film 1013 is removed, and after a p-type GaAs contact layer 1009 has been formed by using the MOVPE method at a growth temperature of 660° C., a p-type electrode 1011/n-type electrode 1012 is formed, and the wafer is then subjected to cleavage so that a semiconductor laser device as shown in FIG. 8 is obtained. In the present invention, the term “wafer” refers to the entire structure of laminated layers including a substrate and respective layers that have been formed thereon through the respective manufacturing processes.

In a conventional window-structure semiconductor laser device, in order to provide energy greater than a band-gap energy corresponding to a laser oscillation wavelength within the impurity diffusion area (window area), the sealed-tube diffusion method in which ZnAs2, which contains Zn atoms having a comparatively large diffusion constant in the AlGaInP-based material, is used as the impurity diffusion source is adopted so that Zn atoms are diffused into the undope GaInP active layer 1004.

In the conventional method, however, Zn atoms having a comparatively large diffusion coefficient in the AlGaInP-based material are used as impurity atoms having the second conductivity in the respective layers 1005 to 1007 serving as exciting areas (active areas), and also used as impurity atoms to be diffused into the undope GaInP active layer 1004 in the impurity diffusion area (window area).

Consequently, in the case when, with respect to the window area formed near the laser resonator end face, Zn atoms are diffused into the above-mentioned undope GaInP active layer 1004 within the impurity diffusion area (window area) so as to make the band-gap energy of the active layer near the light output end face greater than the band-gap energy corresponding to the laser oscillation wavelength, a large amount of Zn atoms that are the second conductive impurity atoms located in the p-type AlGaInP inner clad layer 1005 are diffused into the undope GaInP active layer 1004 also within the exciting area (active area), with the result that there is an increase in the driving current at the time of high output, and the resulting degradation in long-term reliability.

In the case when the above-mentioned diffusion is carried out under conditions which prevent Zn atoms that are the second conductive impurity atoms from diffusing into the undope GaInP active layer 1004 in the exciting area (active area), the diffusion of Zn atoms to the undope GaInP active layer 1004 within the impurity diffusion area (window area) becomes insufficient, with the result that laser light is absorbed in the area near the end face of the resonator.

Consequently, COD tends to occur in the active layer area near the end face of the resonator, causing a reduction in the maximum light output at the time of high-output driving and the resulting degradation in long-term reliability.

### SUMMARY OF THE INVENTION

The present invention is to provide a semiconductor laser device that can reduce a driving current at the time of high output, and is superior in long-term reliability, and a manufacturing method for such a semiconductor laser device.

The semiconductor laser device of the present invention, which is made from an AlGaInP-based material, and has a first clad layer of a first conductivity type, an active layer and a second clad layer of a second conductivity type that are formed over a semiconductor substrate, is arranged so that a portion of the active layer in an area near a laser resonator end face has a peak wavelength in photoluminescence that is smaller than a peak wavelength in photoluminescence in a portion of the active layer in a laser resonator inner area, and the second clad layer of the second conductivity type located in the area near a laser resonator end face contains As atoms.

### BRIEF DESCRIPTION OF THE DRAWING

FIG. 1a is a perspective view that includes a light-outgoing end face in a semiconductor laser device structure in accordance with a first embodiment of the present invention;

FIG. 1b shows a cross-sectional view of a waveguide path taken along line Ia-Ia′ of FIG. 1a;

FIG. 1c shows a cross-sectional view in the layer thickness direction taken along line Ib-Ib′ of FIG. 1a;

FIGS. 2a to 2f show explanatory drawings of a manufacturing method of the semiconductor laser element in accordance with the first embodiment of the present invention;

FIG. 3 is a drawing that shows a distribution of As atoms in the depth direction in an area near a laser resonator end face and a laser resonator inner area of the semiconductor laser element in accordance with the first embodiment of the present invention;

FIG. 4 is a drawing that shows a distribution of Be atoms in the depth direction in an area near a laser resonator end face and a laser resonator inner area inside a ridge of the semiconductor laser element in accordance with the first embodiment of the present invention;

FIG. 5 is a drawing that shows a relationship between an As atom concentration and a wavelength shift in the window area with respect to the wavelength of the active area in the p-type AlₓGa_{y}In_{z}P second clad layer 105 in the area near the laser resonator end face in the manufacturing method of the semiconductor laser device in accordance with a second embodiment of the present invention;

FIG. 6a is a perspective view that includes a light-outgoing end face in a semiconductor laser device structure in accordance with a fourth embodiment of the present invention;

FIG. 6b shows a cross-sectional view of a waveguide path taken along line Ia-Ia′ of FIG. 6a;

FIG. 6c shows a cross-sectional view in the layer thickness direction taken along line Ib-Ib′ of FIG. 6a;

FIGS. 7a to 7e show explanatory drawings of a manufacturing method for the semiconductor laser element in accordance with the fourth embodiment of the present invention;

FIGS. 8a and 8b are schematic cross-sectional views that show a structure of a prior-art semiconductor laser device; and

FIGS. 9a to 9d are explanatory drawings that show a manufacturing method of the prior-art semiconductor laser device.

### DETAILED DESCRIPTION OF THE INVENTION

The present invention relates to a semiconductor laser device, which is made from an AlGaInP-based material, comprising:

a first clad layer of a first conductivity type, an active layer and a second clad layer of a second conductivity type that are formed on a semiconductor substrate,

wherein a portion of said active layer in an area near a laser resonator end face has a peak wavelength in photoluminescence that is smaller than a peak wavelength in photoluminescence in a portion of said active layer in a laser resonator inner area, and the second clad layer of the second conductivity type located in the area near a laser resonator end face contains As atoms.

With the above-mentioned structure, even in the case when the heating temperature of the wafer is lowered with the heating time being shortened, in an attempt to prevent the second conductive impurity atoms in the laser resonator inner area from being diffused into the active layer, the second conductive impurity atoms, contained in the second clad layer of the second conductivity type, are diffused into the area near the laser resonator end face in an accelerating manner so that it becomes possible to disorganize the active layer in the area near the laser resonator end face, and consequently to make the peak wavelength in photoluminescence of the active layer (window area) in the area near the laser resonator end face smaller than the peak wavelength in photoluminescence of the active layer (active area) in the laser resonator inner area. Consequently, since an absorbing area for the wavelength of laser light is not formed in the area near the laser resonator end face, it becomes possible to provide a semiconductor laser device which is superior in the long-term reliability at the time of high-output driving operations, and free from COD.

In the present invention, the AlGaInP-based maternal refers to Ga_{y}In_{z}P (in which y and z are respectively from not less than 0 to not more than 1) and AlₓGa_{y}In_{z}P (x, y and z are respectively from not less than 0 to not more than 1). In the present invention, the clad layer and the active layer are formed by appropriately using the AlGaInP-based material.

The semiconductor substrate to be used in the laser device of the present invention is a semiconductor substrate of III-V group compounds such as GaAs and InP, and GaAs is preferably used from the viewpoint of easiness in lattice matching with the AlGaInP-based material.

In the present specification, the first conductivity type refers to the conductivity type of n-type or p-type, which is formed between the above-mentioned substrate and the active layer. The second conductivity type refers to the conductivity type of n-type or p-type, which is formed on the active layer on the side opposite to the substrate. In the case when the first conductivity type is the n-type, the second conductivity type is the p-type. The present invention is preferably applied to an element having a structure in which the first conductivity type is the n-type and the second conductivity type is the p-type from the viewpoint of current constriction (current blocking) over the active layer.

In the present invention, the area near the laser resonator end face refers to the semiconductor substrate and the respective layers formed over the semiconductor substrate in the vicinity of the laser resonator end face from which laser light is released, and the laser resonator inner area refers to the semiconductor substrate and the respective layers formed over the semiconductor substrate in areas other than the area near the laser resonator end face, and the sizes of the peak wavelength in photoluminescence in the active layer in the area near the laser resonator end face and the peak wavelength in photoluminescence in the active layer in the inner area of the laser resonator are compared with each other based upon a photoluminescence method (PL method).

In the semiconductor laser device of the present invention, the second clad layer of the second conductivity type in the area near the laser resonator end face is allowed to contain As atoms at a concentration in a range from not less than 1×10¹⁸ cm⁻³ to not more than 1×10²⁰ cm⁻³, preferably from not less than 5×10¹⁸ cm⁻³ to not more than 5×10¹⁹ cm⁻³, and the As atom concentration in the second clad layer of the second conductivity type in the area near the laser resonator end face is set to be higher than the As atom concentration in the second clad layer of the second conductivity type in the laser resonator inner area.

With the above-mentioned arrangement, in the process for disorganizing the active layer in the area near the laser resonator end face, it is possible to prevent the second conductive impurity atoms from being diffused into the active layer in the laser resonator inner area, in comparison with the area near the laser resonator end face, and consequently to obtain a semiconductor laser device which can reduce the driving current at the time of high output.

In the semiconductor laser device of the present invention, the As atom concentration in the second clad layer of the second conductivity type in the area near the laser resonator end face is preferably set in a range from not less than 1×10¹⁸ cm⁻³ to not more than 1×10²⁰ cm⁻³, preferably from not less than 5×10¹⁸ cm⁻³ to not more than 5×10¹⁹ cm⁻³.

With the above-mentioned arrangement, the second conductive impurity atoms contained in the second clad layer of the second conductivity type in the area near the laser resonator end face can be diffused in an accelerated manner, and it is possible to prevent transformation into an InGaAsP-based MQW active layer in which the peak wavelength in photoluminescence is extremely great; therefore, it becomes possible to make the peak wavelength in photoluminescence in the active layer (window area) in the area near the laser resonator end face sufficiently smaller than the peak wavelength in photoluminescence in the active layer (active area)in the laser resonator inner area. Consequently, since an absorbing area for the wavelength of laser light is not formed in the area near the laser resonator end face, it becomes possible to provide a semiconductor laser device which is superior in the long-term reliability at the time of high-output driving operations, and free from COD.

In the semiconductor laser device of the present invention, impurity atoms having the second conductivity, contained in the second clad layer of the second conductivity type in the area near a laser resonator end face, are preferably the same as impurity atoms having the second conductivity contained in the second clad layer of the second conductivity type in the laser resonator inner area. With respect to the impurities having the second conductivity, in the case of the p-type, examples thereof include II-group atoms, such as Be, Zn and Mg, preferably Be atoms are used, and in the case of the n-type, examples thereof include Si and Se atoms.

In the case when impurity atoms having the second conductivity, contained in the second clad layer of the second conductivity type in the laser resonator inner area, are Be while impurities having the second conductivity contained in the second clad layer of the second conductivity type in the vicinity of the laser resonator end face are Zn and Be, Zn atoms are diffused at the time of forming the window area. With this arrangement, since the impurity atoms having the second conductivity to be diffusion-controlled in the active layer are limited to only one kind, it becomes possible to prevent the impurity atoms having the second conductivity from being diffused into the active layer in the laser resonator inner area and also to easily control the peak wavelength in photoluminescence in the active layer (window area) in the area near the laser resonator end face. As a result, it becomes possible to improve the long-term reliability at the time of high output and also to reduce the driving current with ease.

In the semiconductor laser device of the present invention, impurity atoms having the second conductivity, contained in the second clad layer of the second conductivity type in the area near the laser resonator end face as well as in the laser resonator inner area, are preferably prepared as II-group atoms having a mass number smaller than the mass number of P atom. With respect to the II-group atoms, examples thereof include Be and Mg, preferably Be.

With respect to the diffusion constant of the II-group atoms having a mass number smaller than the mass number of P atoms, the diffusion constant is greatly increased by allowing the AlGaInP-based material to contain As atoms; therefore, even in the case when the heating temperature of the wafer is lowered and the heating time thereof is shortened, the above-mentioned arrangement makes it possible to disorganize the active layer in the area near the laser resonator end face, and also to make the peak wavelength in photoluminescence of the active layer (window area) in the area near the laser resonator end face smaller than the peak wavelength in photoluminescence of the active layer (active area) in the laser resonator inner area. As a result, since an absorbing area for the wavelength of laser light is not formed in the area near the laser resonator end face, it becomes possible to provide a semiconductor laser device which is superior in the long-term reliability at the time of high-output driving operations, and free from COD.

In the case when Be atoms are applied as the II-group atoms having a mass number smaller than the mass number of P atom, since Be atoms have a small diffusion constant in the AlGaInP material and also have a great diffusion constant in the AlGaInP material containing As atoms, it is possible to disorganize the active layer in the area near the laser resonator end face, and also to simultaneously suppress Be atoms from being diffused into the active layer in the laser resonator inner area; thus, it becomes possible to reduce the driving current at the time of high output, and consequently to provide a semiconductor laser device which is superior in the long-term reliability at the time of high-output driving operations, and free from COD.

In the semiconductor laser device of the present invention, impurity atoms having the second conductivity, contained in the second clad layer of the second conductivity type in the area near the laser resonator end face as well as in the laser resonator inner area, are preferably allowed to have a concentration in a range from not less than 1×10¹⁸ cm⁻³ to not more than 5×10¹⁸ cm⁻³.

With the above-mentioned arrangement, in the area near the laser resonator end face, the impurity atoms having the second conductivity, contained in the second clad layer of the second conductivity, are sufficiently diffused into the active layer, and in the laser resonator inner area, it is possible to suppress the impurity atoms having the second conductivity, contained in the second clad layer of the second conductivity type, from being diffused into the active layer; therefore, it becomes possible to reduce the driving current at the time of high output, and consequently to provide a semiconductor laser device which is superior in the long-term reliability at the time of high-output driving operations, and free from COD.

The semiconductor laser device of the present invention is preferably arranged so that a GaAs contact layer of the second conductivity type is placed over the second clad layer of the second conductivity type in the area near a laser resonator end face and the laser resonator inner area, and a GaInP intermediate layer is placed between the second clad layer of the second conductivity type and the GaAs contact layer of the second conductivity type in the laser resonator inner area.

With the above-mentioned arrangement, a difference in the band-gap energy occurs between the second clad layer of the second conductivity type and the GaAs contact layer of the second conductivity type in the area near the laser resonator end face, making it possible to prevent the current injection to the window area, to suppress carrier loss in the window area, and also to reduce reactive current that does not contribute to light emission; thus, it becomes possible to reduce the driving current at the time of high output, and consequently to provide a semiconductor laser device which is superior in the long-term reliability at the time of high-output driving operations.

The semiconductor laser device of the present invention is preferably arranged so that a GaAs current non-injection layer of the first conductivity type is formed over the second clad layer of the second conductivity type in the area near a laser resonator end face.

With the above-mentioned arrangement, the GaAs current non-injection layer serves as an As atom diffusion source to the second clad layer of the second conductivity type in the area near the laser resonator end face, making it possible to prevent the current injection to the window area, to suppress carrier loss in the window area, and also to reduce reactive current that does not contribute to light emission; thus, it becomes possible to reduce the driving current at the time of high output, and consequently to provide a semiconductor laser device which is superior in the long-term reliability at the time of high-output driving operations.

The semiconductor laser device of the present invention is manufactured through the processes of: allowing a laminated-layer structure that is made from an AlGaInP-based material and contains a first clad layer of a first conductivity type, an active layer and a second clad layer of a second conductivity type to grow over a semiconductor substrate; diffusing As atoms in the second clad layer of the second conductivity type in an area near a laser resonator end face; and diffusing impurity atoms having the second conductivity contained in the second clad layer of the second conductivity type in an area near a laser resonator end face into an active layer so that a portion of the active layer in the area near a laser resonator end face has a peak wavelength in photoluminescence that is smaller than a peak wavelength in photoluminescence in a portion of the active layer in the laser resonator inner area.

By using the above-mentioned manufacturing processes, the second conductive impurity atoms are diffused into the area near the laser resonator end face in an accelerating manner so that it is possible to decrease the heating temperature of a wafer and also to shorten the heating time. Consequently, it becomes possible to make the peak wavelength in photoluminescence of the active layer in the area near the laser resonator end face sufficiently smaller than the peak wavelength in photoluminescence of the active layer in the laser resonator inner area. It also becomes possible to suppress the impurity atoms having the second conductivity located in the second clad layer of the second conductivity type in the laser resonator inner area from being diffused into the active layer; thus, it becomes possible to reduce the driving current at the time of high output, and consequently to provide a semiconductor laser device which is superior in the long-term reliability at the time of high-output driving operations, and free from COD.

In the manufacturing method of the semiconductor laser device of the present invention, the process of diffusing As atoms in the second clad layer of the second conductivity type in the area near a laser resonator end face is provided with the processes of: irradiating the area near a laser resonator end face of the wafer with ionized As atoms; and heating the wafer.

By using the above-mentioned process, the second clad layer of the second conductivity type in the area near the laser resonator end face is allowed to contain As atoms, with the result that even when the heating temperature of the wafer is lowered and the heating time thereof is shortened, it is possible to make the peak wavelength in photoluminescence in the active layer in the area near the laser resonator end face sufficiently smaller than the peak wavelength in photoluminescence in the active layer in the laser resonator inner area. As a result, it becomes possible to provide a semiconductor laser device which is superior in the long-term reliability at the time of high-output driving operations, and free from COD.

In the manufacturing method of the semiconductor laser device of the present invention, the process of heating the wafer is compatibly carried out by a process of forming a current block layer of the first conductivity type.

By using the above-mentioned process, the second clad layer of the second conductivity type in the area near the laser resonator end face is allowed to contain As atoms, simultaneously as the side face of the ridge of the semiconductor laser device is buried with a current blocking layer of the first conductivity type, so that the manufacturing processes can be simplified. It is possible to make the peak wavelength in photoluminescence in the active layer in the area near the laser resonator end face sufficiently smaller than the peak wavelength in photoluminescence in the active layer in the laser resonator inner area, and consequently to provide a semiconductor laser device which is superior in the long-term reliability at the time of high-output driving operations, and free from COD.

The manufacturing method of the semiconductor laser device of the present invention, the process of heating the wafer is compatibly carried out by the process of forming a GaAs current non-injection layer of the first conductivity type over the second clad layer of the second conductivity type in the area near a laser resonator end face.

By using the above-mentioned process, the second clad layer of the second conductivity type in the area near the laser resonator end face is allowed to have As atoms at a high concentration, with the result that even when the heating temperature of the wafer is lowered and the heating time thereof is shortened, it is possible to make the peak wavelength in photoluminescence in the active layer in the area near the laser resonator end face sufficiently smaller than the peak wavelength in photoluminescence in the active layer in the laser resonator inner area, and consequently to provide a semiconductor laser device which is superior in the long-term reliability at the time of high-output driving operations, and free from COD.

In the manufacturing method of the semiconductor laser device of the present invention, the process of diffusing impurity atoms having the second conductivity contained in the second clad layer of the second conductivity type in an area near a laser resonator end face of a wafer into an active layer so that the active layer is allowed to have a smaller peak wavelength in photoluminescence in an area near a laser resonator end face than a peak wavelength in photoluminescence in an laser resonator inner area is compatibly carried out by a step of forming a GaAs contact layer of the second conductivity type.

By using the above-mentioned process, the impurity atoms (Be atoms) having the second conductivity, contained in the second clad layer of the second conductivity type in the area near the laser resonator end face, can be diffused into the active layer in the area near the laser resonator end face so that the peak wavelength in photoluminescence in the active layer in the area near the laser resonator end face is made sufficiently smaller than the peak wavelength in photoluminescence in the active layer in the laser resonator inner area; thus, it is becomes possible to provide a semiconductor laser device which is superior in the long-term reliability at the time of high-output driving operations, and free from COD.

In the manufacturing method of the semiconductor laser device of the present invention, the process of diffusing impurity atoms having the second conductivity contained in the second clad layer of the second conductivity type in the area near a laser resonator end face into an active layer so that the active layer is allowed to have a smaller peak wavelength in photoluminescence in an area near a laser resonator end face than a peak wavelength in photoluminescence in an laser resonator inner area is carried out by a molecular beam epitaxy (MBE) method.

<First Embodiment>

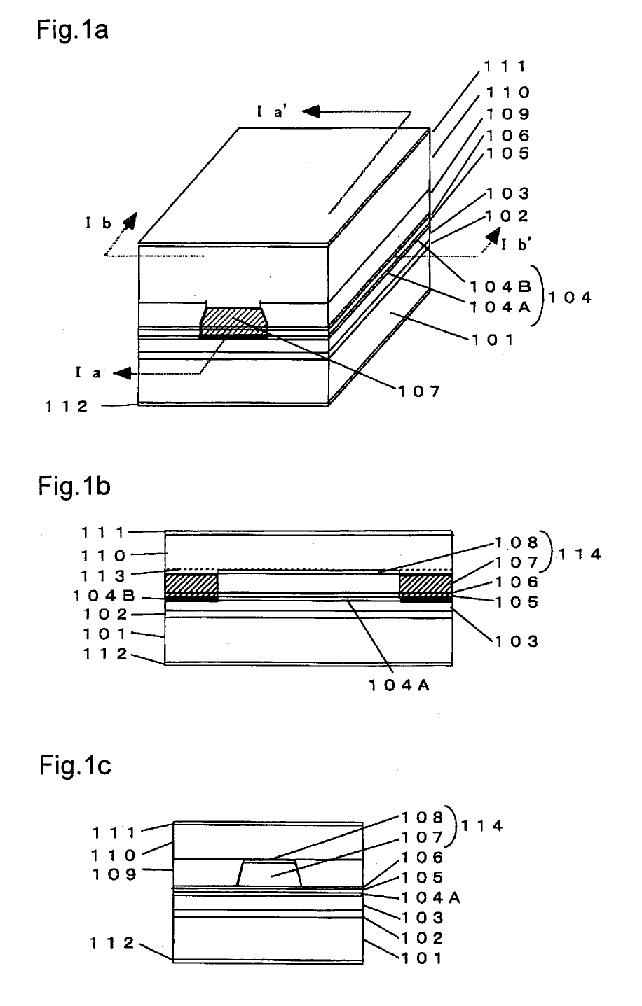

FIG. 1 is an explanatory drawing that shows a structure of a semiconductor laser device in accordance with the first embodiment of the present invention. In FIG. 1, FIG. 1(a) shows a perspective view including a light-outgoing end face, FIG. 1(b) shows a cross-sectional view of a waveguide path in the layer thickness direction, taken along line Ia-Ia′ of FIG. 1(a), and FIG. 1(c) shows a cross-sectional view in the layer thickness direction taken along line Ib-Ib′ of FIG. 1(b). Reference numeral 101 is an n-type GaAs substrate, 102 is an n-type Ga_{y}In_{z}P buffer layer (in which y and z are respectively set from not less than 0 to not more than 1; hereinafter, this description is omitted), 103 is an n-type AlₓGa_{y}In_{z}P first clad layer (x, y and z are respectively set from not less than 0 to not more than 1; hereinafter, this description is omitted), 104 is an active layer (MQW active layer) in which a multiplex quantum well structure, formed by alternately stacking barrier layers and well layers, is sandwiched by light guide layers, 105 is a p-type AlₓGa_{y}In_{z}P second clad layer, 106 is a p-type etching stop layer, 107 is a p-type AlₓGa_{y}In_{z}P third clad layer of ridge stripes aligned in the resonator direction, 108 is a p-type Ga_{y}In_{z}P intermediate layer, 109 is an n-type AlₓIn_{z}P (in which x and z are respectively set from not less than 0 to not more than 1; hereinafter, this description is omitted) current block (constriction) layer that is formed in a manner so as to bury the side faces of the p-type AlₓGa_{y}In_{z}P third clad layer of ridge stripe, 110 is a p-type GaAs contact layer, 111 is a p-side electrode and 112 is an n-side electrode.

In FIG. 1, reference numeral 104A is an MQW active layer (active area) inside a laser resonator, 104B is an area (window area) in which the peak wavelength in photoluminescence in the MQW active layer near a laser resonator end face is smaller than the peak wavelength in photoluminescence in the MQW active layer 104A inside the laser resonator, 113 is a current non-injection area from which the p-type Ga_{y}In_{z}P intermediate layer has been removed, 114 is a striped ridge consisting of the p-type AlₓGa_{y}In_{z}P third clad layer 107 and the p-type Ga_{y}In_{z}P intermediate layer 108. The MQW active layer 104 is constituted by laminated layer structure of a well layer Ga_{y}In_{z}P (y=0.51, z=0.49) (layer thickness 50 Å) and a barrier layer AlₓGa_{y}In_{z}P (x=0.26, y=0.25, z=0.49) (layer thickness 50 Å), the number of the well layers being four.

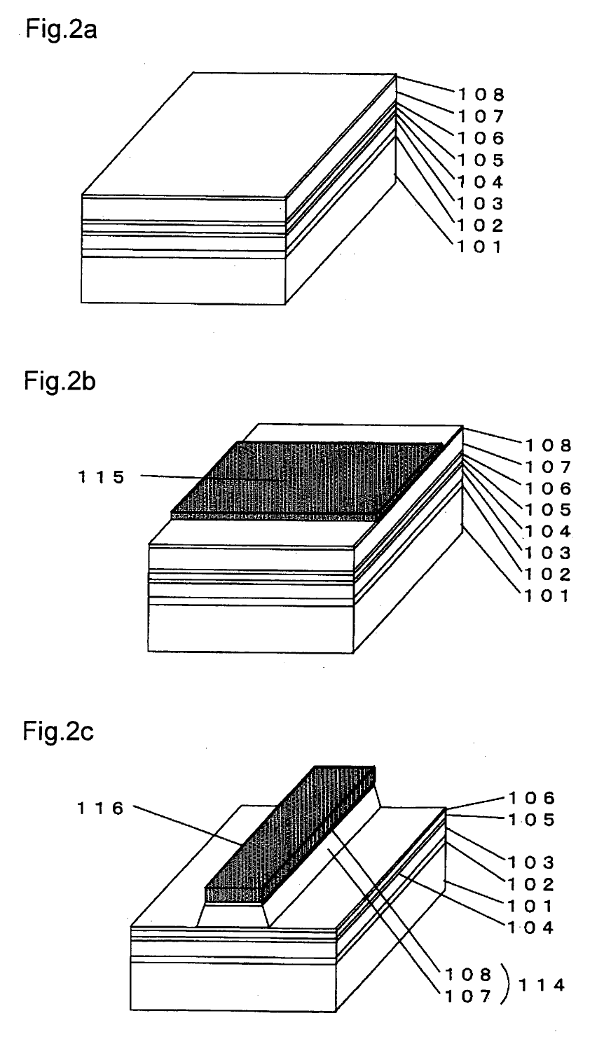

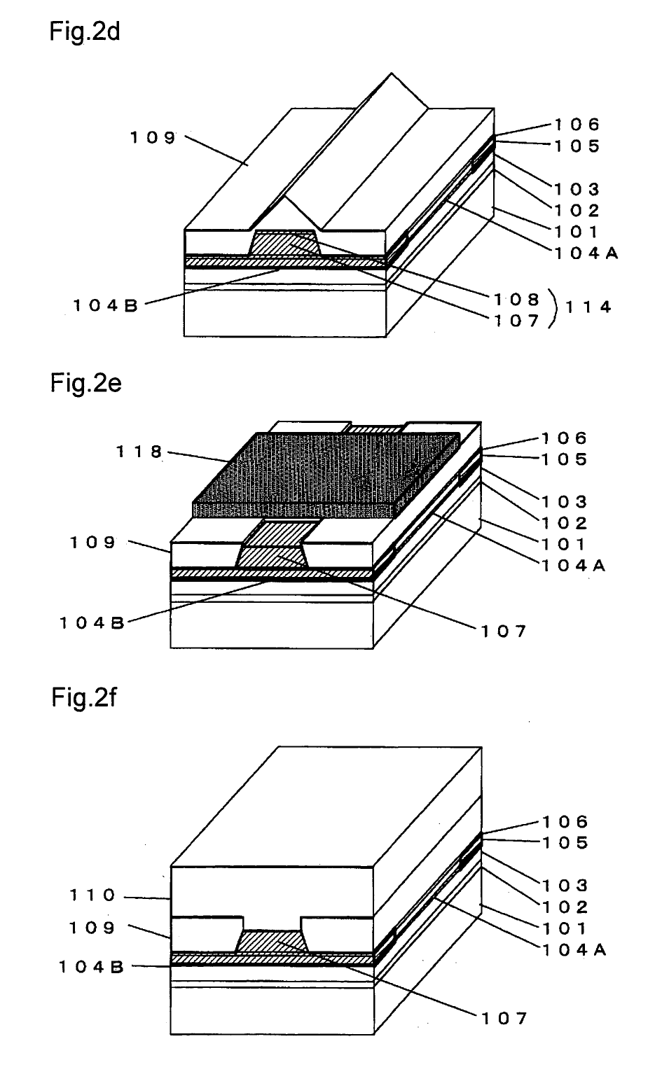

Referring to FIG. 2, the following description will discuss the manufacturing method. On the n-type GaAs substrate 101 (carrier concentration 2×10¹⁸ cm⁻³), the following layers are successively formed by a molecular beam epitaxy (MBE) method (see FIG. 2(a)): the n-type Ga_{y}In_{z}P buffer layer 102 (carrier concentration 1×10¹⁸ cm⁻³) (y=0.51, z=0.49) (layer thickness about 0.2 μm), the n-type AlₓGa_{y}In_{z}P first clad layer 103 (carrier concentration 1×10¹⁸ cm⁻³) (x=0.36, y=0.15, z=0.49) (layer thickness about 2 μm), the MQW active layer 104, the p-type AlₓGa_{y}In_{z}P second clad layer 105 (x=0.36, y=0.15, z=0.49) (layer thickness about 0.2 μm), the p-type etching stop layer 106, the p-type AlₓGa_{y}In_{z}P third clad layer 107 (carrier concentration 2×10¹⁸ cm⁻³) (x=0.36, y=0.15, z=0.49) (layer thickness 1.2 μm) and the p-type Ga_{y}In_{z}P intermediate layer 108 (carrier concentration 1×10¹⁹ cm⁻³) (y=0.51, z=0.49) (layer thickness about 0.05 μm). At this time, Si atoms are contained in the respective layers 101 to 103, and Be atoms, which are II-group atoms having the p-type conductivity, are contained in the respective layers 105 to 108.

By using a known photolithography technique, a striped SiO₂ mask 115 (layer thickness 2000 Å) having a width of 740 μm is formed on the surface of the p-type Ga_{y}In_{z}P intermediate layer 108 in the inner area of a laser resonator in a direction orthogonal to the ridge stripe (FIG. 2(b)). The SiO₂ mask 115 is formed so as to prevent the laser resonator inner area from being irradiated with ionized As atoms.

Thereafter, the surface of the p-type Ga_{y}In_{z}P intermediate layer 108, which forms an area near a laser resonator end face, is irradiated with ionized As atoms. Thus, an As atom diffusion source is formed in the vicinity of a wafer surface in the area near a laser resonator end face.

The SiO₂ mask 115, formed on the surface of the p-type Ga_{y}In_{z}P intermediate layer 108 in the laser resonator inner area, is removed, and a striped resist mask 116 extending in a direction perpendicular to the laser resonator end face is then formed on the p-type Ga_{y}In_{z}P intermediate layer 108; thus, by using a known etching technique, the p-type Ga_{y}In_{z}P intermediate layer 108 and the p-type AlₓGa_{y}In_{z}P third clad layer 107 are formed into a ridge 114 having a striped form with a width of about 3 μm in a manner so as to reach the p-type etching stop layer 106 (FIG. 2(c)).

The striped resist mask 116, formed on the p-type Ga_{y}In_{z}P intermediate layer 108, is removed; thereafter, under conditions of a growth temperature of 500° C. with a growth time of 2 hours, the second MBE process is carried out so that side faces of the ridge 114 formed of the p-type AlₓGa_{y}In_{z}P third clad layer 107 and the p-type Ga_{y}In_{z}P intermediate layer 108 are buried with an n-type AlₓIn_{z}P current block layer 109. At this time, in the area near the laser resonator end face on which the As atom diffusion source has been formed, As atoms are diffused into (up to) the p-type AlₓGa_{y}In_{z}P second clad layer 105 (FIG. 2 (d))

The distribution in the depth direction of As atoms in the area near the laser resonator end face as well as in the laser resonator inner area inside the ridge 114 made of the p-type AlₓGa_{y}In_{z}P third clad layer 107 and the p-type Ga_{y}In_{z}P intermediate layer 108 was measured by a secondary ion mass spectrometer (SIMS).

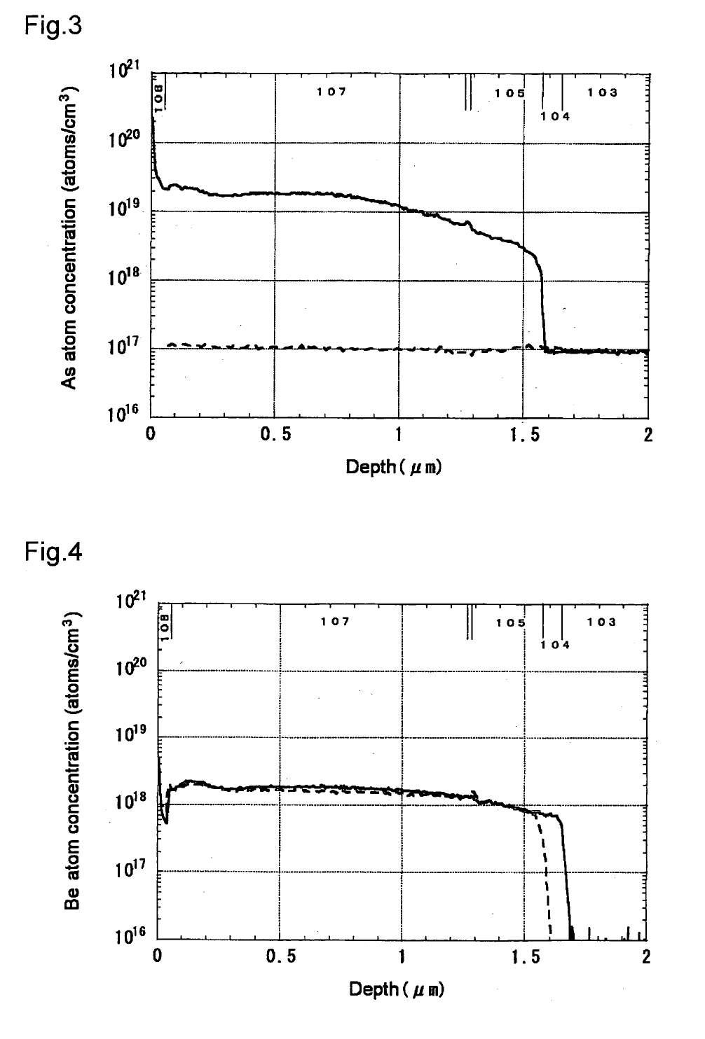

The test results are shown in FIG. 3. The axis of ordinates of FIG. 3 indicates the As atom concentration (cm⁻³), and the axis of abscissas thereof indicates the depth (μm) from the p-type Ga_{y}In_{z}P intermediate layer 108. In FIG. 3, the broken line indicates the distribution of As atoms in the depth direction within the laser resonator inner area, and the solid line indicates the distribution thereof in the area near the laser resonator end face.

As shown in FIG. 3, As atoms exist in the respective layers 105 to 108 in the area near the laser resonator end face, and As atom concentrations in the respective layers 105 to 108 in the area near the laser resonator end face are higher in comparison with those in the respective layers 105 to 108 in the laser resonator inner area.

Based upon these facts, it is clear that the application of the above-mentioned manufacturing method in which the surface of the p-type Ga_{y}In_{z}P intermediate layer 108 that forms the area near the laser resonator end face is irradiated with ionized As atoms, and the second MBE growth process is then carried out so that the side faces of the ridge 114 are then buried with the n-type AlₓIn_{z}P current block layer 109 makes it possible to diffuse As atoms in the p-type AlₓGa_{y}In_{z}P second clad layer 105 that forms the second clad layer of the second conductivity type in the area near the laser resonator end face as well as in the p-type AlₓGa_{y}In_{z}P third clad layer 107.

It is also clear that the application of the above-mentioned manufacturing method makes it possible to provide a higher concentration of As atoms in the p-type AlₓGa_{y}In_{z}P second clad layer 105 that forms the second clad layer of the second conductivity type in the area near the laser resonator end face as well as in the p-type AlₓGa_{y}In_{z}P third clad layer 107, in comparison with the concentration of As atoms in the laser resonator inner area.

With respect to one portion of the wafer that has been subjected to the second MBE growth, the respective wavelengths of the MQW active layer (window area) 104B in the area near the laser resonator end face and the MQW active layer (active area) 104A of the laser resonator inner area were measured by a PL method. As a result, in this state, the light-emission spectrum from the window area 104B has no wavelength shift with respect to the light-emission spectrum from the active area 104A.

Thereafter, by using a known photolithography technique, a resist mask is formed on the surface of the n-type AlₓIn_{z}P current block layer 109 formed on the side faces of the ridge 114, and the n-type AlₓIn_{z}P current block layer 109 formed on the ridge 114 of the resist mask opening section is selectively removed by using a known etching technique.

After the resist mask formed on the n-type AlₓIn_{z}P current block layer 109 has been removed, a resist mask 118 having a width of 740 μm is again formed in the laser resonator inner area by using a known photolithography technique, and the p-type Ga_{y}In_{z}P intermediate layer 108 on the opening section of resist mask 118 is selectively removed (FIG. 2(e)).

The opening section of the resist mask 118 is formed right above the MQW active layer (window area) 104B in the area near the laser resonator end face. With this arrangement, a difference in band-gap energy is generated between the p-type AlₓGa_{y}In_{z}P third clad layer 107 in the area near the laser resonator end face and the p-type GaAs contact layer 110 so that a current non-injection area 113 is formed. Since the current non-injection area 113 formed through the above-mentioned processes is located right above the window area 104B, it becomes possible to prevent a current injection into the window area, and consequently to reduce a reactive current that does not contribute to light emission.

Thereafter, the resist mask 118 formed on the laser resonator inner area is removed, and under conditions of a growth temperature of 600° C. and a growth time of 2 hours, the third MBE process is carried out so that a p-type GaAs contact layer 110 is formed (FIG. 2(f)).

FIG. 4 shows the distribution of Be atoms in the depth direction in the area near the laser resonator end face and the laser resonator inner area inside the ridge 114 of the semiconductor laser device of the present embodiment obtained through the above-mentioned manufacturing method.

The distribution in the depth direction of Be atoms shown in FIG. 4 is based on the results of measurements by a secondary ion mass spectrometer (SIMS). In FIG. 4, the axis of ordinates indicates the Be atom concentration (cm⁻³), and the axis of abscissas thereof indicates the depth (μm) from the p-type Ga_{y}In_{z}P intermediate layer 108. In FIG. 4, the broken line indicates the distribution of Be atoms in the depth direction within the laser resonator inner area, and the solid line indicates the distribution thereof in the area near the laser resonator end face.

As shown in FIG. 4, there is no diffusion of Be atoms into the MQW active layer (active area) in the laser resonator inner area. In the MQW active layer (window area) 104B in the area near the laser resonator end face, Be atoms diffused from the respective layers 105 to 108 exist.

With respect to one portion of the wafer that has been subjected to the third MBE growth by using the manufacturing method of the semiconductor laser device of the present embodiment, the respective wavelengths of the MQW active layer (window area) 104B in the area near the laser resonator end face and the MQW active layer (active area) 104A of the laser resonator inner area were measured by a photoluminescence (PL) method.

As a result, in the case when the manufacturing method of the semiconductor laser device of the present embodiment, the light-emission spectrum from the window area 104B has a wavelength shift of 40 nm toward the short-wavelength side of the light-emission spectrum from the active area 104A.

The reason for this is explained as follows: since the impurity atoms having the second conductivity type, contained in the p-type AlₓGa_{y}In_{z}P second clad layer 105 that forms the second clad layer of the second conductivity type in the area near the laser resonator end face and the laser resonator inner area, as well as in the p-type AlₓGa_{y}In_{z}P third clad layer 107, are II-group atoms having a mass number smaller than the mass number of P atom, the diffusion constant of the II-group atoms having a mass number smaller than the mass number of P atom is greatly increased by allowing the p-type AlₓGa_{y}In_{z}P second clad layer 105 that forms the second clad layer of the second conductivity type and the p-type AlₓGa_{y}In_{z}P third clad layer 107 to contain As atoms; thus, by heating the wafer during the third MBE growth, it is possible to make the peak wavelength in photoluminescence of the MQW active layer (window area) 104B in the area near the laser resonator end face sufficiently smaller than the peak wavelength in photoluminescence of the MQW active layer (active area) 104A in the laser resonator inner area.

A p-electrode 111 is formed on the top face thereof, and an n-electrode 112 is formed on the bottom face thereof.

A scribe line is formed virtually in the center of the area near the laser resonator end face having a width of 60 μm so that it is divided into bars with the length of the resonator, and light-outgoing faces on both of the sides of each bar are finally coated with reflection layers; further, this is divided into chips so that a semiconductor laser device having a window area of about 30 μm and a current non-injection area formed on the laser resonator end face of a resonator having a length of 800 μm is manufactured.

The characteristics of the semiconductor laser device obtained by the manufacturing method of the present embodiment were measured.

For comparison, the characteristics of a prior art semiconductor laser device that was formed by diffusing Zn atoms up to the mid way of the n-type AlₓGa_{y}In_{z}P first clad layer 103 in the area near the laser resonator end face in the manufacturing method of the present invention were also measured simultaneously.

The results show that the oscillating frequency (μ) at CW50 mW of the semiconductor laser device of the present embodiment and the prior-art semiconductor laser device is 655 nm, the driving current (Iop) at CW50 mW of the semiconductor laser device of the present embodiment is 100 mA and the driving current (Iop) at CW50 mW of the prior-art semiconductor laser device is 130 mA.

As the results of maximum light output tests, the semiconductor laser devices of the present invention and the prior art were found to be free from COD even at a light output of not less than 300 mW. When these were subjected to reliability tests of 50 mW at 70° C., the average service life of the semiconductor laser device of the present embodiment was improved to about 5,000 hours, as compared with the average service life of 1,000 hours in the prior-art semiconductor laser device.

As described above, it is clear that the semiconductor laser device of the present embodiment makes it possible to reduce the driving current and also to improve the long-term reliability.

In the semiconductor laser device of the present embodiment in which As atoms are contained in the second clad layers of the second conductivity type in the area near the laser resonator end face (the p-type AlₓGa_{y}In_{z}P second clad layer 105 and the p-type AlₓGa_{y}In_{z}P third clad layer 107), even when the heating temperature (anneal temperature) of the wafer is lowered and the heating time (anneal time) thereof is shortened so as to prevent the impurity atoms (Be atoms) having the second conductivity in the laser resonator inner area from being diffused into the active layer, the impurity atoms (Be atoms) having the second conductivity, contained in the second clad layers 105, 107 of the second conductivity type, are diffused in an accelerating manner in the area near the laser resonator end face; therefore, it becomes possible to disorganize the active layer in the area near the laser resonator end face, and consequently to make the peak wavelength in photoluminescence of the active layer (window area 104B) in the area near the laser resonator end face smaller than the peak wavelength in photoluminescence of the active layer (active area 104A) in the laser resonator inner area.

Consequently, an absorbing area for the wavelength of laser light is not formed in the vicinity of the laser resonator end face so that it becomes possible to provide a semiconductor laser device that is free from COD and has improved long-term reliability in high-output driving operations.

In the semiconductor laser device of the present invention in which the As atom concentration in the second clad layers of the second conductivity type (the p-type AlₓGa_{y}In_{z}P second clad layer 105 and the p-type AlₓGa_{y}In_{z}P third clad layer 107) in the area near the laser resonator end face is set to a higher level in comparison with the As atom concentration in the second clad layers 105, 107 of the second conductivity type in the laser resonator inner area, with respect to the process of disorganizing the active layer in the area near the laser resonator end face, it is possible to suppress the impurity atoms (Be atoms) having the second conductivity from being diffused into the active layer (active area 104A) in the resonator inner area in comparison with the area near the laser resonator end face; therefore, it becomes possible to reduce the driving current at the time of high-output operations.

In the semiconductor laser device of the present invention in which the impurity atoms (Be atoms) having the second conductivity, contained in the second clad layers of the second conductivity type (the p-type AlₓGa_{y}In_{z}P second clad layer 105 and the p-type AlₓGa_{y}In_{z}P third clad layer 107) in the area near the laser resonator end face are the same as impurity atoms (Be atoms) having the second conductivity, contained in the second clad layers of the second conductivity (the p-type AlₓGa_{y}In_{z}P second clad layer 105 and the p-type AlₓGa_{y}In_{z}P third clad layer 107) in the laser resonator inner area, since the impurity atoms having the second conductivity that need to be controlled when diffused into the active layers 104A and 104B are limited to atoms of one kind, it becomes possible to easily suppress the impurity atoms (Be atoms) having the second conductivity from being diffused into the active layer 104A in the laser resonator inner area, and also to easily control the peak wavelength in photoluminescence of the active layer 104B in the area near the laser resonator end face. Consequently, it becomes possible to improve the long-term reliability and also to easily reduce the driving current, at the time of high-output driving operations.

In the semiconductor laser device of the present embodiment, with respect to the impurity atoms having the second conductivity contained in the second clad layers of the second conductivity type (the p-type AlₓGa_{y}In_{z}P second clad layer 105 and the p-type AlₓGa_{y}In_{z}P third clad layer 107) in the area near the laser resonator end face as well as in the laser resonator inner area, Be atoms, which are II-group atoms that have a small diffusion constant among AlGaInP-based materials, exert a great diffusion constant in the AlGaInP-based material containing As atoms, and have a mass number smaller than the mass number of P atoms, are adopted; therefore, it is possible to suppress Be atoms from being diffused into the active layer in the laser resonator inner area and simultaneously to disorder the active layer in the area near the laser resonator end face; thus, it becomes possible to reduce the driving current at the time of high-output operations. Besides Be, Mg may be used, but Be is more preferably used from the viewpoint of diffusing suppression with respect to the active layer.

In the present embodiment, the SiO₂ mask 115 is formed so as not to irradiate the laser resonator inner area with ionized As atoms; however, another film may be used with the same effects, as long as it is a dielectric film such as SiₐN_{b} and SiₐO_{b}N_{c} (in which a, b and c are not less than 1).

In the present invention, the p-type Ga_{y}In_{z}P intermediate layer 108 in the area near the laser resonator end face inside the ridge 114 is selectively removed to form the current non-injection area 113; however, another current non-injection area, obtained by a manufacturing method in which the n-type AlₓIn_{z}P current block layer 109 formed on the ridge 114 is allowed to remain only in the area near the laser resonator end face, may be used, and this method also prevents current injection into the window area, and reduces reactive current that does not contribute to light emission so that the same effects as described above are obtained.

<Second Embodiment>

With respect to the semiconductor laser device of the present invention described in the first embodiment, the present embodiment discusses a relationship between the As atom concentration and the wavelength shift amount in the window area with respect to the wavelength of the active area in the p-type AlₓGa_{y}In_{z}P second clad layer 105 that is the second clad layer of the second conductivity type in the area near the laser resonator end face.

In the manufacturing method described in the first embodiment, the quantity of irradiation (quantity of dose) of ionized As atoms is changed so as to set the As atom concentration in the p-type AlₓGa_{y}In_{z}P second clad layer 105 that is the second clad layer of the second conductivity type in the area near the laser resonator end face to respective values of 1×10¹⁷ cm⁻³, 5×10¹⁷ cm⁻³, 1×10¹⁸ cm⁻³, 5×10¹⁸ cm⁻³, 1×10¹⁹ cm⁻³, 5×10¹⁹ cm⁻³, 1×10²⁰ cm⁻³, 5×10²⁰ cm⁻³ and 1×10²¹ cm⁻³, so that the surface of each of p-type Ga_{y}In_{z}P intermediate layers 108 forming the areas near the laser resonator end faces for nine sheets of wafers is irradiated with ionized As atoms under the above-mentioned nine conditions.

With respect to each of the nine wafers, by using known photolithography technique and etching technique, the p-type Ga_{y}In_{z}P intermediate layer 108 and the p-type AlₓGa_{y}In_{z}P third clad layer 107 are formed into a striped ridge 114 having a width of about 3 μm.

Thereafter, under conditions at a growth temperature of 500° C. with a growth time of 2 hours, each of the nine sheets of wafers was subjected to the second MBE process so that the side faces of the ridge 114 made of the p-type AlₓGa_{y}In_{z}P third clad layer 107 and the p-type Ga_{y}In_{z}P intermediate layer 108 were buried with an n-type AlₓIn_{z}P current block layer 109. At this time, As atoms were diffused to the p-type Al_{z}Ga_{y}In_{z}P second clad layer 105 in the area near the laser resonator end face having the As atom diffusion source formed therein.

With respect to one portion of each of the nine sheets of wafers that had been subjected to the second MBE growth, the respective wavelengths of the MQW active layer (window area) 104B in the area near the laser resonator end face and the MQW active layer (active area) 104A of the laser resonator inner area were measured by a PL method. As a result, in the case when the As atom concentration in the p-type AlₓGa_{y}In_{z}P second clad layer 105 that is the second clad layer of the second conductivity type in the area near the laser resonator end face is in a range of not less than 1×10¹⁷ cm⁻³ to not more than 1×10²⁰ cm⁻³, no wavelength shift is found in with respect to the light-emitting spectrum from the active area 104A; however, in the case of the wafers in which the As atom concentration in the p-type AlₓGa_{y}In_{z}P second clad layer 105 that is the second clad layer of the second conductivity type in the area near the laser resonator end face is set to 5×10²⁰ cm⁻³ and 1×10²¹ cm⁻³, the light-emitting spectrum from the window area 104B is wavelength-shifted toward the long wavelength side with respect to the light-emitting spectrum from the active area 104A.

Thereafter, under conditions of a growth temperature of 600° C. with a growth time of 2 hours, the third MBE process was carried out so that a p-type GaAs contact layer 110 was formed.

With respect to one portion of each of the nine sheets of wafers that had been subjected to the third MBE growth, the respective wavelengths of the MQW active layer (window area) 104B in the area near the laser resonator end face and the MQW active layer (active area) 104A of the laser resonator inner area were measured by a PL method.

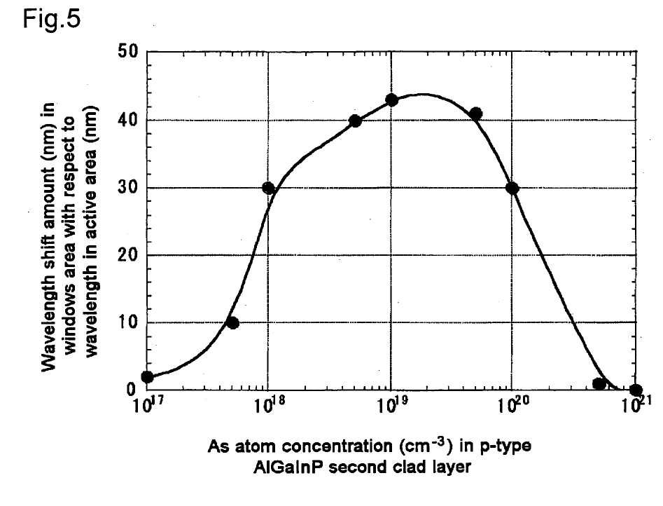

FIG. 5 shows the relationship between the As atom concentration and the wavelength shift amount in the window area with respect to the wavelength of the active area in the p-type AlₓGa_{y}In_{z}P second clad layer 105 that is the second clad layer of the second conductivity type in the area near the laser resonator end face. In this case, the concentration of impurity atoms (Be atom) having the second conductivity that are contained in the p-type AlₓGa_{y}In_{z}P second clad layer 105 and the p-type AlₓGa_{y}In_{z}P third clad layer 107 that are the second clad layers of the second conductivity type is set to 2×10¹⁸ cm⁻³, and all the wavelengths in the window area are shifted toward the short-wavelength side with respect to the wavelength in the active area. The axis of ordinates of FIG. 5 indicates the wavelength shift amount (nm) of the window area with respect to the wavelength in the active area, and the axis of abscissas thereof indicates the As atom concentration (cm⁻³) in the p-type AlₓGa_{y}In_{z}P second clad layer 105.

As shown in FIG. 5, in a range of the As atom concentration of not less than 1×10¹⁸ cm⁻³ to not more than 1×10²⁰ cm⁻³ in the p-type AlₓGa_{y}In_{z}P second clad layer 105, the wavelength in the window area is shifted toward the short wavelength side by not less than 30 nm with respect to the wavelength in the active area. The reason for this is explained as follows: As the amount of mixture of As atoms in the semiconductor layer formed by an AlGaInP-based material increases, the diffusion rate of Be atoms that are II-group atoms having a mass number smaller than that of P atom also increases; however, in the case when the As atom concentration in the p-type AlₓGa_{y}In_{z}P second clad layer 105 is not more than 1×10¹⁸ cm⁻³, the diffusion rate of Be atoms that are II-group atoms abruptly drops and the diffusion of Be atoms that are II-group atoms is not accelerated, with the result that the Be atoms do not reach the active layer (window area) 104B in the area near the laser resonator end face. In the case when the As atom concentration in the p-type AlₓGa_{y}In_{z}P second clad layer 105 is not less than 1×10²⁰ cm⁻³, the amount of mixture of As atoms in the MQW active layer (window area) 104B near the laser resonator end face abruptly increases to form an InGaAsP-based MQW active layer having a very large peak wavelength in photoluminescence so that Be atoms are sufficiently diffused in the active layer (window area) 104B in the area near the laser resonator end face; therefore, even when the active layer is disordered, the peak wavelength in photoluminescence of the active layer (window area 104B) in the area near the laser resonator end face is not made sufficiently smaller than the peak wavelength in photoluminescence of the active layer (active area 104A) in the laser resonator inner area.

By using the manufacturing method described in the first embodiment, nine kinds of semiconductor laser devices were manufactured with the As atom concentration in the p-type AlₓGa_{y}In_{z}P second clad layer 105 that is the second clad layer of the second conductivity type in the area near the laser resonator end face being set to respective values of 1×10¹⁷ cm⁻³, 5×10¹⁷ cm⁻³, 1×10¹⁸ cm⁻³, 5×10¹⁸ cm⁻³, 1×10¹⁹ cm⁻³, 5×10¹⁹ cm⁻³, 1×10²⁰ cm⁻³, 5×10²⁰ cm⁻³ and 1×10²¹ cm⁻³, and with respect to these semiconductor laser devices, the maximum light output tests were conducted.

As a result, in the case of the five kinds of semiconductor devices that were manufactured so as to be set in the range of not less than 1×10¹⁸ cm⁻³ to not more than 1×10²⁰ cm⁻³, with the wavelength in the window area being shifted toward the short wavelength side by not less than 30 nm with respect to the wavelength of the active area, these semiconductor devices were free from COD even under a light output of not less than 300 mW; however, in the case of the four kinds of semiconductor devices that were manufactured to be set to not more than 5×10¹⁷ cm⁻³ as well as to not less than 5×10²⁰ cm⁻³, these semiconductor devices caused COD on the resonator end face under a light output of not more than 150 mW.

Based upon these facts, the above-mentioned semiconductor laser device is preferably designed to have an As atom concentration in the p-type AlₓGa_{y}In_{z}P second clad layer 105 that is the second clad layer of the second conductivity type in the area near the laser resonator end face in a range of not less than 1×10¹⁸ cm⁻³ to not more than 1×10²⁰ cm⁻³; thus, the peak wavelength in photoluminescence of the active layer (window area 104B) in the area near the laser resonator end face can be made sufficiently smaller than the peak wavelength in photoluminescence of the active layer (active area 104A) in the laser resonator inner area, thereby making it possible to provide a semiconductor laser element that is free from COD.

<Third Embodiment>

With respect to the semiconductor laser device of the present invention described in the first embodiment, the present embodiment discusses the impurity atom (Be atom) concentration having the second conductivity, contained in the p-type AlₓGa_{y}In_{z}P second clad layer 105 and the p-type AlₓGa_{y}In_{z}P third clad layer 107 that are the second clad layers of the second conductivity type.

In the manufacturing method described in the first embodiment, on seven sheets of n-type GaAs substrates 101 were successively formed respective layers of 102 to 108 through epitaxial growth by using an MBE method so as to set the concentration of impurity atoms (Be atoms) having the second conductivity in the p-type AlₓGa_{y}In_{z}P second clad layer 105 and the p-type AlₓGa_{y}In_{z}P third clad layer 107 that are the second clad layer of the second conductivity type to each of seven values of 5.0×10¹⁷ cm⁻³, 7.5×10¹⁷ cm⁻³, 1×10¹⁸ cm⁻³, 2.5 ×10¹⁸ cm⁻³, 5×10¹⁸ cm⁻³, 7.5×10¹⁸ cm⁻³ and 1×10¹⁹ cm⁻³.

A striped SiO₂ mask 115 is formed on each of the laser resonator inner areas of the seven wafers so as not to be irradiated with ionized As atoms, and the area near the laser resonator end face is then irradiated with ionized As atoms.

With respect to each of the seven wafers, by using known photolithography technique and etching technique, the p-type Ga_{y}In_{z}P intermediate layer 108 and the p-type AlₓGa_{y}In_{z}P third clad layer 107 are formed into a striped ridge 114 having a width of about 3 μm.

Thereafter, under conditions at a growth temperature of 500° C. with a growth time of 2 hours, each of the seven sheets of wafers was subjected to the second MBE process so that the side faces of the ridge 114 made of the p-type AlₓGa_{y}In_{z}P third clad layer 107 and the p-type Ga_{y}In_{z}P intermediate layer 108 were buried with an n-type AlₓIn_{z}P current block layer 109. At this time, As atoms were diffused to the p-type AlₓGa_{y}In_{z}P second clad layer 105 in the area near the laser resonator end face having the As atom diffusion source formed therein.

With respect to one portion of each of the seven sheets of wafers, the respective wavelengths of the MQW active layer (window area) 104B in the area near the laser resonator end face and the MQW active layer (active area) 104A of the laser resonator inner area were measured by a PL method. As a result, at this time, the light-emission spectrum from the window area 104B was not wavelength-shifted with respect to the light-emission spectrum from the active area 104A.

Thereafter, under conditions of a growth temperature of 600° C. with a growth time of 2 hours, the third MBE process was carried out so that a p-type GaAs contact layer 110 was formed.

With respect to one portion of each of the seven sheets of wafers that had been subjected to the third MBE growth, the respective wavelengths of the MQW active layer (window area) 104B in the area near the laser resonator end face and the MQW active layer (active area) 104A of the laser resonator inner area were measured by a PL method. As a result, in the five kinds of wafers in which the concentration of impurity atoms (Be atoms) having the second conductivity in the p-type AlₓGa_{y}In_{z}P second clad layer 105 and the p-type AlₓGa_{y}In_{z}P third clad layer 107 that are the second clad layers of the second conductivity type is not less than 1×10¹⁸ cm⁻³, the wavelength in the window area was shifted toward the short wavelength side by not less than 30 nm with respect to the wavelength in the active area.

The reason for this is explained as follows: when the concentration of impurity atoms (Be atoms) having the second conductivity in the p-type AlₓGa_{y}In_{z}P second clad layer 105 and the p-type AlₓGa_{y}In_{z}P third clad layer 107 that are the second clad layers of the second conductivity type is not less than 1×10¹⁸ cm⁻³, Be atoms are sufficiently diffused in the active layer (window area) 104B in the area near the laser resonator end face so that the active layer is disorderd; therefore, the peak wavelength in photoluminescence of the active layer (window area 104B) in the area near the laser resonator end face becomes smaller than the peak wavelength in photoluminescence in the active layer (active area 104A) in the laser resonator inner area.

By using the manufacturing method described in the first embodiment, seven kinds of semiconductor laser devices were manufactured with the concentration of impurity atoms (Be atoms) having the second conductivity in the p-type AlₓGa_{y}In_{z}P second clad layer 105 and the p-type AlₓGa_{y}In_{z}P third clad layer 107 that are the second clad layers of the second conductivity type being set to respective values of 5.0×10¹⁷ cm⁻³, 7.5×10¹⁷ cm⁻³, 1×10¹⁸ cm⁻³, 2.5×10¹⁸ cm⁻³, 5×10¹⁸ cm⁻³, 7.5×10¹⁸ cm⁻³ and 1×10¹⁹ cm⁻³, and measurements were carried out on characteristics of these semiconductor laser devices.

The results show that in the five kinds of semiconductor laser devices in which the concentration of impurity atoms (Be atoms) having the second conductivity in the p-type AlₓGa_{y}In_{z}P second clad layer 105 and the p-type AlₓGa_{y}In_{z}P third clad layer 107 that are the second clad layers of the second conductivity type is set to not more than 5×10¹⁸ cm⁻³, the driving current (Iop) at CW 50 mW is not more than 120 mA. The results of maximum light output tests show that, in the five kinds of semiconductor laser devices in which the concentration of impurity atoms (Be atoms) having the second conductivity in the second clad layers 105, 107 of the second conductivity type is set to not less than 1×10¹⁸ cm⁻³, with the wavelength in the window area being shifted toward the short wavelength side by not less than 30 nm with respect to the wavelength in the active area, these semiconductor laser devices are free from COD even under a light output of not less than 300 mW.

Based upon these facts, the above-mentioned semiconductor laser device is preferably designed to have a concentration of impurity atoms (Be atoms) having the second conductivity in the p-type AlₓGa_{y}In_{z}P second clad layer 105 and the p-type AlₓGa_{y}In_{z}P third clad layer 107 that are the second clad layers of the second conductivity type in a range of not less than 1×10¹⁸ cm⁻³ to not more than 5×10¹⁸ cm⁻³; thus, it is possible to achieve a disordered state by diffusing the impurity atoms (Be atoms) having the second conductivity to the active layer (window area 104B) in the area near the laser resonator end face and also to achieve suppression in diffusion of the impurity atoms (Be atoms) having the second conductivity into the active layer (active area 104A) in the laser resonator inner area. Therefore, it becomes possible to reduce the driving current at the time of high output, and consequently to provide a semiconductor laser device which is superior in the long-term reliability, and free from COD.

<Fourth Embodiment>

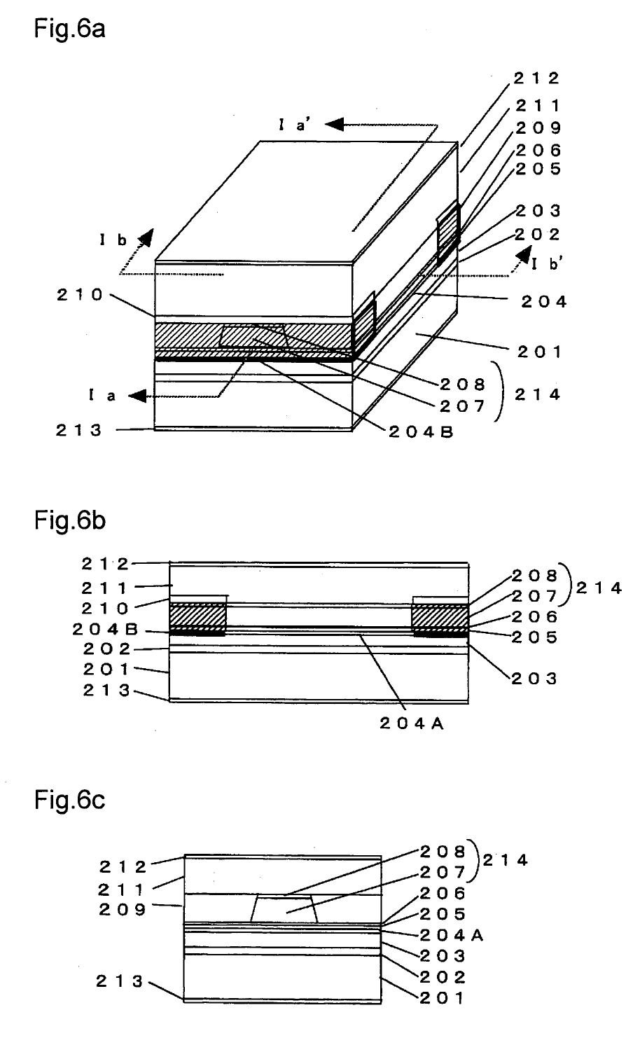

FIG. 6 is an explanatory drawing that shows a structure of a semiconductor laser device in accordance with the fourth embodiment of the present invention. In FIG. 6, FIG. 6(a) shows a perspective view including a light-outgoing end face, FIG. 6(b) shows a cross-sectional view of a waveguide path in the layer thickness direction, taken along line Ia-Ia′ of FIG. 6(a), and FIG. 6(c) shows a cross-sectional view in the layer thickness direction taken along line Ib-Ib′ of FIG. 6(a). Reference numeral 201 is an n-type GaAs substrate, 202 is an n-type Ga_{y}In_{z}P buffer layer (in which y and z are respectively set from not less than 0 to not more than 1; hereinafter, this description is omitted), 203 is an n-type AlₓGa_{y}In_{z}P first clad layer (x, y and z are respectively set from not less than 0 to not more than 1; hereinafter, this description is omitted), 204 is an active layer (MQW active layer) in which a multiplex quantum well structure, formed by alternately stacking barrier layers and well layers, is sandwiched by light guide layers, 205 is a p-type AlₓGa_{y}In_{z}P second clad layer, 206 is a p-type etching stop layer, 207 is a p-type AlₓGa_{y}In_{z}P third clad layer made of ridge stripes aligned in the resonator direction, 208 is a p-type Ga_{y}In_{z}P intermediate layer, 209 is an n-type AlₓIn_{z}P (in which x and z are respectively set from not less than 0 to not more than 1; hereinafter, this description is omitted) current block (constriction) layer that is formed in a manner so as to bury the side faces of the p-type AlₓGa_{y}In_{z}P third clad layer made of ridge stripes, 210 is an n-type GaAs current non-injection layer, 211 is a p-type GaAs contact layer, 212 is a p-side electrode and 213 is an n-side electrode.

In FIG. 6, reference numeral 204A is an MQW active layer (active area) inside a laser resonator, 204B is an area (window area) in which the peak wavelength in photoluminescence in the MQW active layer near a laser resonator end face is smaller than the peak wavelength in photoluminescence in the MQW active layer 204A inside the laser resonator, 214 is a striped ridge consisting of the p-type AlₓGa_{y}In_{z}P third clad layer 207 and the p-type Ga_{y}In_{z}P intermediate layer 208. The MQW active layer 204 is constituted by four laminated well layers, that is, a well layer Ga_{y}In_{z}P (y=0.51, z=0.49) (layer thickness 50 Å) and a barrier layer AlₓGa_{y}In_{z}P (x=0.26, y=0.25, z=0.49) (layer thickness 50 Å).

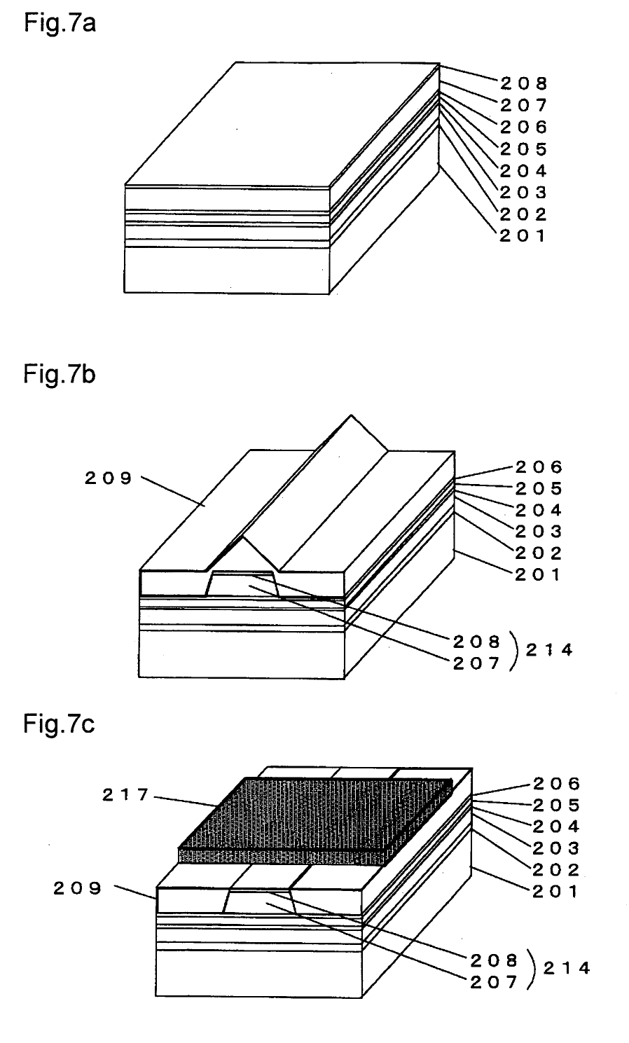

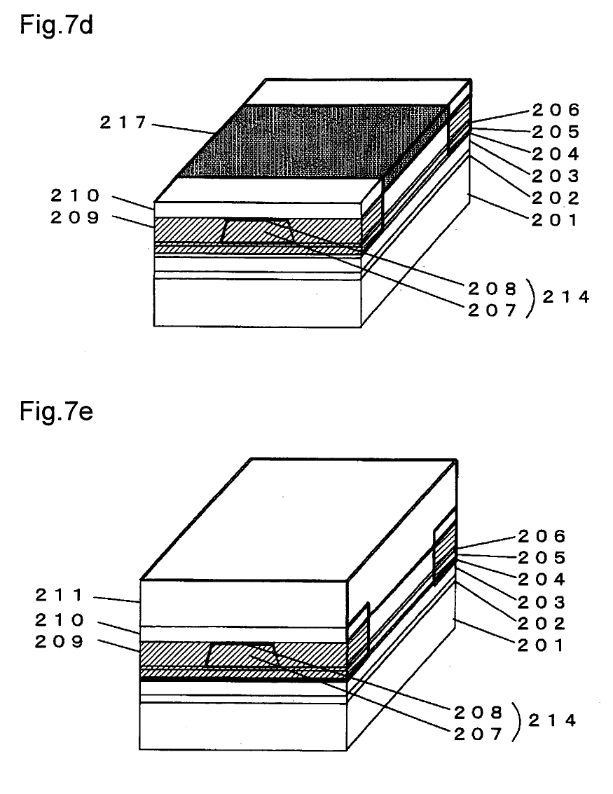

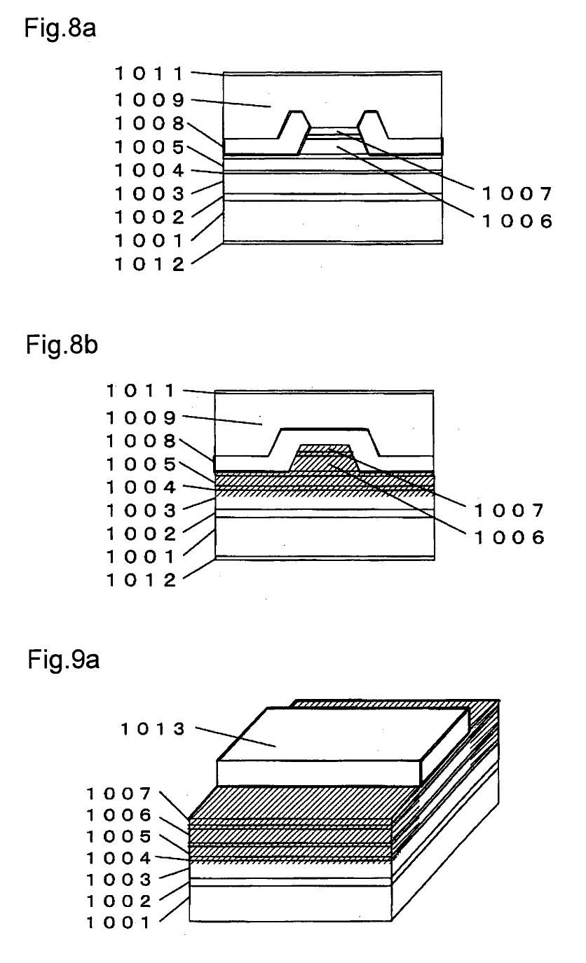

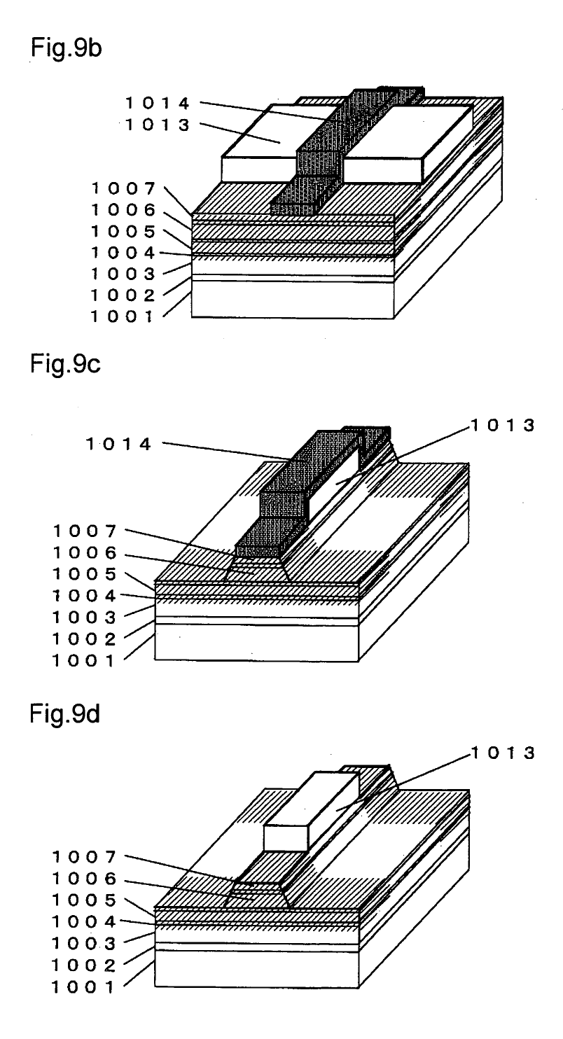

Referring to FIG. 7, the following description will discuss the manufacturing method. On the n-type GaAs substrate 201 (carrier concentration 2×10¹⁸ cm⁻³), the following layers are successively formed by a molecular beam epitaxy (MBE) method (see FIG. 7(a)): the n-type Ga_{y}In_{z}P buffer layer 202 (carrier concentration 1×10¹⁸ cm⁻³) (y=0.51, z=0.49) (layer thickness about 0.2 μm), the n-type AlₓGa_{y}In_{z}P first clad layer 203 (carrier concentration 1×10¹⁸ cm⁻³) (x=0.36, y=0.15, z=0.49) (layer thickness about 2 μm), the MQW active layer 204, the p-type AlₓGa_{y}In_{z}P second clad layer 205 (carrier concentration 2×10¹⁸ cm⁻³) (x=0.36, y=0.15, z=0.49) (layer thickness about 0.2 μm), the p-type etching stop layer 206, the p-type AlₓGa_{y}In_{z}P third clad layer 207 (carrier concentration 2×10¹⁸ cm⁻³) (x=0.36, y=0.15, z=0.49) (layer thickness 1.2 μm) and the p-type Ga_{y}In_{z}P intermediate layer 208 (carrier concentration 1×10¹⁹ cm⁻³) (y=0.51, z=0.49) (layer thickness about 0.05 μm). At this time, Si atoms are contained in the respective layers 201 to 203, and Be atoms, which are II-group atoms having the p-type conductivity, are contained in the respective layers 205 to 208.

Thereafter, by using a known photolithography technique, a striped resist mask extending in a direction perpendicular to the laser resonator end face is formed on the surface of the p-type Ga_{y}In_{z}P intermediate layer 208, and by using a known etching technique, the p-type Ga_{y}In_{z}P intermediate layer 208 and the p-type AlₓGa_{y}In_{z}P third clad layer 207 are formed into a ridge 214 having a striped shape with a width of about 3 μm in a manner so as to reach the p-type etching stop layer 206.

The striped resist mask formed on the p-type Ga_{y}In_{z}P intermediate layer 208 is removed. Thereafter, the second MBE process is carried out so that side faces of the ridge 214 made of the p-type AlₓGa_{y}In_{z}P third clad layer 207 and the p-type Ga_{y}In_{z}P intermediate layer 208 are buried with an n-type AlₓIn_{z}P current block layer 209 (FIG. 7 (b)).

Thereafter, by using a known photolithography technique, a resist mask is formed on the surface of the n-type AlₓIn_{z}P current block layer 209 formed on the side faces of the ridge 214, and the n-type AlₓIn_{z}P current block layer 209 formed on the ridge 214 of the resist mask opening section is selectively removed by using a known etching technique.

The resist mask formed on the n-type AlₓIn_{z}P current block layer 210 is removed. Then, by using a known photolithography technique, a striped SiO₂ mask 217 having a width of 740 μm is formed on the surface of the p-type Ga_{y}In_{z}P intermediate layer 208 and the n-type AlₓIn_{z}P current block layer 209 in the laser resonator inner area in a direction orthogonal to the ridge stripe, and the surface of the p-type Ga_{y}In_{z}P intermediate layer 208 and the n-type AlₓIn_{z}P current block layer 209 that form the area near the laser resonator end face is irradiated with ionized As atoms (FIG. 7(c)).

Under conditions at a growth temperature of 500° C. with a growth time of 1 hour, the third MBE process is carried out so that a n-type GaAs current non-injection layer 210 is formed on the surface of the p-type Ga_{y}In_{z}P intermediate layer 208 and the n-type AlₓIn_{z}P current block layer 209 that forms the area near the laser resonator end face, and is not covered with the SiO₂ mask 217 (FIG. 7(d)). Thus, it is possible to diffuse As atoms in the area near the laser resonator end face, and also to simultaneously form the current non-injection layer (area).

The distribution in the depth direction of As atoms in the area near the laser resonator end face and the laser resonator inner area of the wafer was measured by a secondary ion mass spectrometer (SIMS). The measurements were simultaneously carried out on a comparative wafer in which the n-type GaAs current non-injection layer 210 was formed in the area near the laser resonator end face without irradiating the area near the laser resonator end face with ionized As atoms, by using the manufacturing method of the above-mentioned embodiment.

As a result, in the wafer obtained by the manufacturing method of the present embodiment, As atoms exist in the respective layers 205 to 208 in the area near the laser resonator end face, and the concentration of As atoms in each of the layers of 205 to 208 in the area near the laser resonator end face is higher in comparison with each of the layers of 205 to 208 in the laser resonator inner area. However, in the case of the comparative wafer in which the area near the laser resonator end face is not irradiated with ionized As atoms, although As atoms exist in the p-type Ga_{y}In_{z}P intermediate layer 208 in the area near the laser resonator end face, no As atoms exist in each of the layers 205 to 207 in the area near the laser resonator end face.

Based upon these facts, it is clear that, in order to diffuse As atoms in the p-type AlₓGa_{y}In_{z}P second clad layer 205 and the p-type AlₓGa_{y}In_{z}P third clad layer 207 that are the second clad layers of the second conductivity type in the area near the laser resonator end face, at least a process for irradiating the area near the laser resonator end face of the wafer with ionized As atoms is required.

By using the above-mentioned manufacturing method, it is positively possible to make the As atom concentration in the p-type AlₓGa_{y}In_{z}P second clad layer 205 and the p-type AlₓGa_{y}In_{z}P third clad layer 207 that are the second clad layers of the second conductivity type in the area near the laser resonator end face higher than an As atom concentration in the laser resonator inner area.

With respect to one portion of the wafer that had been subjected to the third MBE growth, the respective wavelengths of the MQW active layer (window area) 204B in the area near the laser resonator end face and the MQW active layer (active area) 204A in the laser resonator inner area were measured by a PL method. As a result, at this time, the light-emitting spectrum from the window area 204B was not wavelength-shifted with respect to the light-emitting spectrum from the active area 204A.

Thereafter, the SiO₂ mask 217, formed on the surface of the p-type Ga_{y}In_{z}P intermediate layer 208 and the n-type AlₓIn_{z}P current block layer 209 in the laser resonator inner area, was removed, and under conditions of a growth temperature of 600° C. and a growth time of 2 hours, the fourth MBE process was carried out so that a p-type GaAs contact layer 211 was formed (FIG. 7(e)).

The distribution in the depth direction of Be atoms in the area near the laser resonator end face as well as in the laser resonator inner area inside the ridge of the semiconductor laser element of the present embodiment obtained by the above-mentioned manufacturing method was measured by a secondary ion mass spectrometer (SIMS).

As a result, there was no diffusion of Be atoms into the MQW active layer (active area) in the laser resonator inner area. In the MQW active layer (window area) 204B in the area near the laser resonator end face, Be atoms diffused from the respective layers 205 to 208 existed.

With respect to one portion of the wafer that had been subjected to the fourth MBE growth (formation of the p-type GaAs contact layer 211) by using the manufacturing method of the semiconductor laser device of the present embodiment, the respective wavelengths of the MQW active layer (window area) 204B in the area near the laser resonator end face and the MQW active layer (active area) 204A in the laser resonator inner area were measured by a PL method. For comparison, in the manufacturing method of the semiconductor laser element of the present embodiment, in place of the third MBE growth (formation of the n-type GaAs contact layer 210), an annealing process was carried out for one hour at a substrate temperature of 500° C., and the p-type GaAs contact layer 211 was then subjected to an MBE growth. With respect to one portion of the comparative wafer, the respective wavelengths of the MQW active layer (window area) in the area near the laser resonator end face and the MQW active layer (active area) in the laser resonator inner area were measured.

As a result, in the case of the comparative wafer having no n-type GaAs current non-injection layer 210 formed thereon, the light-emitting spectrum from the window area is wavelength-shifted toward the short wavelength side by 20 nm from the light-emitting spectrum from the active area; in contrast, in the case of the wafer having the n-type GaAs current non-injection layer 210 formed thereon, provided by using the manufacturing method of a semiconductor laser element of the present embodiment, the light-emitting spectrum from the window area 204B was wavelength-shifted toward the short wavelength side by 40 nm from the light-emitting spectrum from the active area 204A.

The reason for this is explained as follows: the area near the laser resonator end face is irradiated with ionized As atoms, and the n-type GaAs current non-injection layer 210 is then formed over the p-type AlₓGa_{y}In_{z}P second clad layer 205 and the p-type AlₓGa_{y}In_{z}P third clad layer 207 that form the second clad layers of the second conductivity type in the area near the laser resonator end face so that the As atom concentration in the p-type AlₓGa_{y}In_{z}P second clad layer 205 and the p-type AlₓGa_{y}In_{z}P third clad layer 207 that form the second clad layers of the second conductivity type in the area near the laser resonator end face is set to a high level, with the result that the impurity atoms (Be atoms) having the second conductivity, contained in the p-type AlₓGa_{y}In_{z}P second clad layer 205 and the p-type AlₓGa_{y}In_{z}P third clad layer 207 that are the second clad layers of the second conductivity type, are diffused in an accelerating manner.

Based upon these facts, by using processes in which the area near the laser resonator end face is irradiated with ionized As atoms and the n-type GaAs current non-injection layer 210 is then formed over the p-type AlₓGa_{y}In_{z}P second clad layer 205 and the p-type AlₓGa_{y}In_{z}P third clad layer 207 that form the second clad layers of the second conductivity type in the area near the laser resonator end face, it becomes possible to make the peak wavelength in photoluminescence of the active layer (window area 204B) in the area near the laser resonator end face sufficiently smaller than the peak wavelength in photoluminescence of the active layer (active area 204A) in the laser resonator inner area.

A p-electrode 212 is formed on the top face of the wafer, and an n-electrode 213 is formed on the bottom face thereof. Then, a scribe line is formed virtually in the center of the area near the laser resonator end face having a width of 60 μm so that it is divided into bars with the length of the resonator, and light-outgoing faces on both of the sides of each bar are coated with reflection layers; further, this is divided into chips so that a semiconductor laser device having a window area of about 30 μm and a current non-injection area formed on the laser resonator end face of a resonator having a length of 800 μm is manufactured. The characteristics of the semiconductor laser device obtained by the manufacturing method of the present embodiment were measured.

For comparison, a semiconductor laser device which had a current non-injection area formed by selectively removing the p-type Ga_{y}In_{z}P intermediate layer from the area near the laser resonator end face, and was formed by the manufacturing method of the first embodiment, was also prepared, and the characteristics of this semiconductor laser device were simultaneously measured.

The results show that the oscillating frequency (λ) at CW50 mW of the semiconductor laser device of the present embodiment and the semiconductor laser device of the first embodiment is 655 nm, the driving current (Iop) at CW50 mW of the semiconductor laser device of the present embodiment is 90 mA and the driving current (Iop) at CW50 mW of the semiconductor laser device of the first embodiment is 100 mA.

As the results of maximum light output tests, the semiconductor laser device of the present embodiment and the semiconductor laser device of the first embodiment are found to be free from COD even at a light output of not less than 300 mW. When these were subjected to reliability tests of 50 mW at 70° C., the average service life of the semiconductor laser device of the present embodiment was improved to 3,000 hours, as compared with the average service life of 2,000 hours in the semiconductor laser device of the first embodiment. Thus, it is clear that the semiconductor laser device of the present embodiment makes it possible to reduce the driving current and also to improve the long-term reliability.

In the semiconductor laser element of the present embodiment, the heat energy to be applied to the semiconductor laser element after the irradiation of ionized As atoms onto the wafer up to the formation of the p-type GaAs contact layer 211 (the third MBE growth at a growth temperature of 500° C. with a growth time of 1 hour, the fourth MBE growth at a growth temperature of 600° C. with a growth time of 2 hours) is reduced in comparison with the case in which the manufacturing method of the first embodiment (the second MBE growth at a growth temperature of 500° C. with a growth time of 2 hours, the third MBE growth at a growth temperature of 600° C. with a growth time of 2 hours); therefore, it is possible to further suppress impurity atoms (Be atoms) that have the second conductivity and are contained in the second clad layers 205 and 207 of the second conductivity type in the laser resonator inner area from diffusing into the active layer (active area 204A) in the laser resonator inner area, and consequently to achieve a reduced current in the driving current. The reduced driving current makes it possible to suppress an increase in the device temperature of the semiconductor laser device at the time of a high-output driving operation, and consequently to improve the long-term reliability in high-output driving operations.

In the present embodiment, the SiO₂ mask 217 is formed so as not to irradiate the laser resonator inner area with ionized As atoms; however, another film may be used with the same effects, as long as it is a dielectric film such as SiₐN_{b} and SiₐO_{b}N_{c} (in which a, b and c are not less than 1).

In the present invention, the n-type GaAs current non-injection layer 210 is formed on the surface of the p-type Ga_{y}In_{z}P intermediate layer 208 and the n-type AlₓIn_{z}P current block layer 209 that form the area near the laser resonator end face; however, another arrangement in which the p-type Ga_{y}In_{z}P intermediate layer 208 in the area near the laser resonator end face inside the ridge 214 is selectively removed, and the n-type GaAs current non-injection layer 210 is then formed may be used, and since this arrangement also prevents a current injection into the window area and reduces a reactive current that does not contribute to light emission, the same effects as described above can be obtained.

In accordance with the present invention, it becomes possible to make the peak wavelength in photoluminescence of the active layer in the area near the laser resonator end face smaller than the peak wavelength in photoluminescence of the active layer in the laser resonator inner area; consequently, it becomes possible to provide a semiconductor laser device (AlGaInP based device) which is superior in the long-term reliability at the time of high-output driving operations, and free from COD.

What is claimed is:

1. A semiconductor laser device, which is made from an AlGaInP-based material, comprising:
a first clad layer of a first conductivity type, an active layer and a second clad layer of a second conductivity type that are formed over a semiconductor substrate,
wherein a portion of said active layer in an area near a laser resonator end face has a peak wavelength in photoluminescence that is smaller than a peak wavelength in photoluminescence in a portion of said active layer in a laser resonator inner area, and the second clad layer of the second conductivity type located in the area near a laser resonator end face contains As atoms.

2. The semiconductor laser device according to claim 1, wherein the As atom concentration of the second clad layer of the second conductivity type in the area near a laser resonator end face is higher than an As atom concentration of the second clad layer of the second conductivity type in the laser resonator inner area.

3. The semiconductor laser device according to claim 1 or 2, wherein the As atom concentration of the second clad layer of the second conductivity type in the area near a laser resonator end face is set in a range from not less than 1×10¹⁸ cm⁻³ to not more than 1×10²⁰ cm⁻³.

4. The semiconductor laser device according to any one of claims 1 to 3, wherein impurity atoms having the second conductivity, contained in the second clad layer of the second conductivity type in the area near a laser resonator end face are the same as impurity atoms having the second conductivity contained in the second clad layer of the second conductivity type in the laser resonator inner area.

5. The semiconductor laser device according to claim 4, wherein the impurity atoms having the second conductivity, contained in the second clad layer of the second conductivity type in the area near a laser resonator end face and the laser resonator inner area, are II-group atoms that have a mass number smaller than the mass number of P atom.

6. The semiconductor laser device according to claim 5, wherein II-group atoms that have a mass number smaller than the mass number of P atom are Be atoms.

7. The semiconductor laser device according to any one of claims 4 to 6, wherein the impurity atoms having the second conductivity, contained in the second clad layer of the second conductivity type in the area near a laser resonator end face and the laser resonator inner area have a concentration in a range from not less than 1×10¹⁸ cm⁻³ to not more than 5×10¹⁸ cm⁻³.

8. The semiconductor laser device according to any one of claims 1 to 7, wherein: a GaAs contact layer of the second conductivity type is formed over the second clad layer of the second conductivity type in the area near a laser resonator end face and the laser resonator inner area, and a GaInP intermediate layer of the second conductivity type is formed between the second clad layer of the second conductivity type and the GaAs contact layer of the second conductivity type in the laser resonator inner area.

9. The semiconductor laser device according to any one of claims 1 to 8, wherein a GaAs current non-injection layer of the second conductivity type is formed over the second clad layer of the second conductivity type in the area near a laser resonator end face.

10. A manufacturing method of a semiconductor laser device, comprising the steps of:
allowing a laminated-layer structure that is made from an AlGaInP-based material and contains a first clad layer of a first conductivity type, an active layer and a second clad layer of a second conductivity type to grow over a semiconductor substrate;
diffusing As atoms in the second clad layer of the second conductivity type in an area near a laser resonator end face; and
diffusing impurity atoms having the second conductivity, contained in the second clad layer of the second conductivity type in the area near a laser resonator end face, into an active layer so that a portion of said active layer in the area near a laser resonator end face has a peak wavelength in photoluminescence that is smaller than a peak wavelength in photoluminescence in a portion of said active layer in the laser resonator inner area.

11. The manufacturing method of a semiconductor laser device according to claim 10, wherein the step of diffusing As atoms in the second clad layer of the second conductivity type in the area near a laser resonator end face comprises the steps of: irradiating the area near a laser resonator end face of a wafer with ionized As atoms; and heating the wafer.

12. The manufacturing method of a semiconductor laser device according to claim 11, wherein the step of heating the wafer is compatibly carried out by a step of forming a current block layer of the first conductivity type.

13. The manufacturing method of a semiconductor laser device according to claim 11, wherein the step of heating the wafer is compatibly carried out by a step of forming a GaAs current non-injection layer of the first conductivity type over the second clad layer of the second conductivity type in the area near a laser resonator end face.

14. The manufacturing method of a semiconductor laser device according to claim 10, wherein the step of diffusing impurity atoms having the second conductivity type contained in the second clad layer of the second conductivity type in an area near a laser resonator end face of the wafer into an active layer so that a portion of said active layer in the area near a laser resonator end face has a peak wavelength in photoluminescence that is smaller than a peak wavelength in photoluminescence in a portion of said active layer in the laser resonator inner area is compatibly carried out by a step of forming a GaAs contact layer of the second conductivity type.

15. The manufacturing method of a semiconductor laser device according to claim 10 or 14, wherein the step of diffusing impurity atoms having the second conductivity type contained in the second clad layer of the second conductivity type in an area near a laser resonator end face of the wafer into an active layer so that a portion of said active layer in the area near a laser resonator end face has a peak wavelength in photoluminescence that is smaller than a peak wavelength in photoluminescence in a portion of said active layer in the laser resonator inner area is carried out by a molecular beam epitaxy (MBE) method.
